(19) United States
(12) Patent Application Publication
(10) Pub. No.: US 2025/0216462 A1
(43) Pub. Date: Jul. 3, 2025

(54) BATTERY DIAGNOSIS METHOD AND BATTERY SYSTEM FOR PROVIDING THE SAME

(71) Applicant: LG ENERGY SOLUTION, LTD., Seoul (KR)

(72) Inventors: Sung Ju HONG, Daejeon (KR); Dong Hyun KIM, Daejeon (KR); Hyo Seong AN, Daejeon (KR); Geon CHOI, Daejeon (KR)

(73) Assignee: LG ENERGY SOLUTION, LTD., Seoul (KR)

(21) Appl. No.: 18/851,546

(22) PCT Filed: Jan. 27, 2023
(86) PCT No.: PCT/KR2023/001309

§ 371 Date: Sep. 26, 2024

(30) Foreign Application Priority Data
May 4, 2022 (KR) 10-2022-0055702

(51) Int. Cl. G01R 31/367; G01R 31/388; G01R 31/389

(52) U.S. Cl. CPC G01R 31/367; G01R 31/388; G01R 31/389

(57) ABSTRACT

The present invention relates a battery system including a battery that includes a plurality of battery banks each of which includes a plurality of battery cells, and a control unit configured to determine a ratio of second state-of-charge change amounts of each battery bank to a first state-of-charge change amount of a reference battery bank, and diagnose defects of each battery bank by comparing the ratio with a diagnosis reference value, when a predetermined diagnosis condition is satisfied in a charging mode of charging the battery with an electricity of an external device, wherein the diagnosis reference value is determined based on a number of battery cells connected in parallel in a battery bank.

### CROSS-REFERENCE TO RELATED APPLICATION

This application is a national stage filing of PCT/KR2023/001309, filed on Jan. 27, 2023, which claims priority to and the benefit of Korean Patent Application No. 10-2022-0055702 filed in the Korean Intellectual Property Office on May 4, 2022, the entire contents of which are incorporated herein by reference.

### TECHNICAL FIELD

The present invention relates to a battery diagnosis method of diagnosing the states of battery banks on the basis of the internal resistance and the states of charge (SOC), and a battery system for providing the method.

### BACKGROUND ART

Recently, as the demand for portable electronic goods such as laptops, video cameras, and portable phones has rapidly increased, and the development of electric vehicles, energy storage batteries, robots, satellites, and so on has accelerated, research on high-performance batteries capable of repetitive charging and discharging has been actively conducted.

The currently commercialized batteries include nickel cadmium batteries, nickel hydrogen batteries, nickel zinc batteries, lithium batteries, etc., and among them, lithium batteries have freedom to be charged and discharged since they have less memory effect as compared to nickel-based batteries, and have very low self-discharge rates and high energy densities. For these advantages, they are getting the spotlight.

In general, batteries each of which includes a plurality of battery cells connected are used depending on the purpose of use. For example, a battery bank including a plurality of battery cells connected in parallel in order to increase the capacity may be used, or a battery bank including a plurality of battery cells connected in series in order to increase the output voltage may be used.

Battery banks have difficulties in terms of cost and structure in monitoring each of the battery cells connected in parallel. In general, batteries including at least one battery bank have a structural feature that they cannot be easily decomposed and separated in order to improve the stability against impact. Therefore, there are difficulties in diagnosing whether each of the battery cells included in battery banks is defective.

Further, in the case where a battery includes a plurality of battery banks, and some battery cells included in some battery banks are defective, the battery may be damaged by an inrush current which is caused by a difference in capacity between a plurality of battery banks.

### DISCLOSURE

### Technical Problem

The present invention has been made in an effort to provide a battery diagnosis method capable of accurately diagnosing the state of a battery including a plurality of battery cells, and a battery system for providing the method.

### Technical Solution

An exemplary embodiment of the present invention provides a battery system including a battery that includes a plurality of battery banks each of which includes a plurality of battery cells, and a control unit configured to control a ratio of second state-of-charge change amounts of each battery bank to a first state-of-charge change amount of a reference battery bank, and diagnose defects of each battery bank by comparing the ratio with a diagnosis reference value, when a predetermined diagnosis condition is satisfied in a charging mode of charging the battery with electricity of an external device, wherein the diagnosis reference value is determined based on the number of battery cells connected in parallel in a respective battery bank.

The diagnosis reference value may be determined by a following equation:

$${Th}_{1} = \frac{m}{m - n} \qquad Equation$$

wherein Th₁ is the diagnosis reference value, m is the number of battery cells connected in parallel in the battery bank, and n is a natural number smaller than m.

The battery system may, in the charging mode, when a first diagnosis condition that at least one battery bank should reaches a full charge state and a second diagnosis condition that the second state-of-charge change amount of each of the plurality of battery banks is equal to or larger than a condition reference value including the first state-of-charge change amount of the reference battery bank, are satisfied, have the control unit diagnose a defect of the plurality of battery banks.

The control unit may be further configured to determine a first reference resistance and a resistance deviation on the basis of a plurality of first internal resistance values related to the plurality of battery banks, and determining a first resistance zone based on the first reference resistance and the resistance deviation, determine, as target banks, a plurality of battery banks having internal resistance values smaller than the first reference resistance among the plurality of battery banks, determine a second reference resistance on the basis of a plurality of second internal resistance values related to a plurality of target banks, and determine a second resistance zone based on the second reference resistance and a parallel deviation corresponding to a connection structure of the plurality of battery cells included in each target bank, and determine, as the reference battery bank, a battery bank having an internal resistance value belonging to the first resistance zone and the second resistance zone among the plurality of battery banks.

Another exemplary embodiment of the present invention provides a battery system including a battery that includes a plurality of battery banks each of which includes a plurality of battery cells, and a control unit configured to determine first diagnosis banks based on an internal resistance of the plurality of battery banks, determine second diagnosis banks by comparing a ratio of a second state-of-charge change amounts of battery banks to a first state-of-charge change amount of a reference battery bank with a diagnosis reference value, when a predetermined diagnosis condition is satisfied in a charging mode of charging the battery with electricity of an external device, and diagnose, as defective battery banks, battery banks determined as the first diagnosis banks and the second diagnosis banks among the plurality of battery banks, wherein the diagnosis reference value is determined based on a number of battery cells connected in parallel in a respective battery bank.

The diagnosis reference value may be determined by a following equation:

$${Th}_{1} = \frac{m}{m - n} \qquad Equation$$

wherein Th₁ is the diagnosis reference value, m is the number of battery cells connected in parallel in a battery bank, and n is a natural number smaller than m.

The battery system may, in the charging mode, when a first diagnosis condition that at least one battery bank should reach a full charge state and a second diagnosis condition that the second state-of-charge change amount of each of the plurality of battery banks should be equal to or larger than a condition reference value including the first state-of-charge change amount of the reference battery bank, are satisfied, have the control unit determine the second diagnosis banks.

The control unit may be further configured to determine a first reference resistance and a resistance deviation on the basis of a plurality of first internal resistance values related to the plurality of battery banks, and determining a first resistance zone based on the first reference resistance and the resistance deviation, determine, as target banks, a plurality of battery banks having internal resistance values smaller than the first reference resistance among the plurality of battery banks, determine a second reference resistance on the basis of a plurality of second internal resistance values related to a plurality of target banks, and determine a second resistance zone based on the second reference resistance and a parallel deviation corresponding to a connection structure of the plurality of battery cells included in each target bank, and determine, as the first diagnosis bank, a battery bank having an internal resistance value which is out of the first resistance zone or the second resistance zone among the plurality of battery banks.

The control unit may be further configured to determine, as the reference battery bank, a battery bank having an internal resistance value belonging to the first resistance zone and the second resistance zone among the plurality of battery banks.

The control unit may be further configured to determine a median value of the plurality of first internal resistance values as the first reference resistance; and determine an absolute deviation between the first reference resistance and the internal resistance of the plurality of battery banks, and convert the absolute deviation into the resistance deviation, using a predetermined scale constant.

The control unit may be further configured to determine a first upper threshold by adding the resistance deviation to the first reference resistance, and determine a first lower threshold by subtracting the resistance deviation from the first reference resistance, and determine the first resistance zone based on the first upper threshold and the first lower threshold.

The control unit may be further configured to determine an average of the plurality of second internal resistance values as the second reference resistance, and determine a parallel coefficient based on the number of battery cells connected in parallel included in each target bank, and determine the parallel deviation by multiplying the parallel coefficient and the second reference resistance together.

The control may be further configured to determine a second upper threshold by adding the parallel deviation to the second reference resistance, determine a second lower threshold by subtracting the parallel deviation from the second reference resistance, and determine the second resistance zone based on the second upper threshold and the second lower threshold.

The control unit may be further configured to determine an average of the plurality of second internal resistance values as the second reference resistance, and determine a parallel coefficient based on the number of battery cells connected in parallel included in each target bank, and determine the parallel deviation by multiplying the parallel coefficient and the second reference resistance together.

The control may be further configured to determine a second upper threshold by adding the parallel deviation to the second reference resistance, determine a second lower threshold by subtracting the parallel deviation from the second reference resistance, and determine the second resistance zone based on the second upper threshold and the second lower threshold.

The battery system may further include a measuring unit that is configured to measure a bank voltage, which is a voltage between both terminals of each of the plurality of battery banks, and a bank current which is a current flowing through each of the plurality of battery banks, and a storage unit that is configured to store an internal resistance value and a state of charge (SOC) which is estimated based on at least one of the bank voltage and the bank current.

Yet another exemplary embodiment of the present invention provides a battery diagnosis method which is a method of diagnosing defects of a battery including a plurality of battery banks each of which includes a plurality of battery cells, and includes a first defect diagnosis step of determining first diagnosis banks based on an internal resistance of the plurality of battery banks, a second defect diagnosis step of determining second diagnosis banks by comparing a ratio of second state-of-charge change amounts of battery banks to a first state-of-charge change amount of a reference battery bank with a diagnosis reference value, when a predetermined diagnosis condition is satisfied in a charging mode of charging the battery with an electricity of an external device, and a diagnosis confirming step of diagnosing, as defective battery banks, battery banks determined as the first diagnosis banks and the second diagnosis banks among the plurality of battery banks, wherein the diagnosis reference value is determined based on a number of battery cells connected in parallel in a respective battery bank.

The diagnosis reference value is determined by a following equation:

$${Th}_{1} = \frac{m}{m - n} \qquad Equation$$

wherein Th₁ is the diagnosis reference value, m is the number of battery cells connected in parallel in a battery bank, and n is a natural number smaller than m.

The battery diagnosis method may further include wherein in the charging mode, when a first diagnosis condition that at least one battery bank should reach a full charge state and a second diagnosis condition that the second state-of-charge change amount of each of the plurality of battery banks should be equal to or larger than a condition reference value including the first state-of-charge change amount of the reference battery bank, are satisfied, the second defect diagnosis step determines the second diagnosis banks.

The first defect diagnosis step may further include a step of determining a first reference resistance and a resistance deviation on the basis of a plurality of first internal resistance values related to the plurality of battery banks, and determining a first resistance zone based on the first reference resistance and the resistance deviation, a step of determining, as target banks, a plurality of battery banks having internal resistance values smaller than the first reference resistance among the plurality of battery banks, and determining a second reference resistance on the basis of a plurality of second internal resistance values related to a plurality of target banks, and determining a second resistance zone on the basis of the second reference resistance and a parallel deviation corresponding to a connection structure of the plurality of battery cells included in each target bank, and a step of determining the first diagnosis banks and the reference battery bank by comparing the internal resistance value of each of the plurality of battery banks with the first resistance zone and the second resistance zone.

The step of determining the first resistance zone may include determining a median value of the plurality of first internal resistance values as the first reference resistance, and determining an absolute deviation between the first reference resistance and the internal resistance of the plurality of battery banks, and converting the absolute deviation into the resistance deviation, using a predetermined scale constant.

The step of determining the first resistance zone may further include determining a first upper threshold by adding the resistance deviation to the first reference resistance, determining a first lower threshold by subtracting the resistance deviation from the first reference resistance, and determining the first resistance zone based on the first upper threshold and the first lower threshold.

The step of determining the second resistance zone may include determining an average of the plurality of second internal resistance values as the second reference resistance, and determining a parallel coefficient based on the number of battery cells connected in parallel included in each target bank, and determining the parallel deviation by multiplying the parallel coefficient and the second reference resistance together.

The step of determining the second resistance zone may further include determining a second upper threshold by adding the parallel deviation to the second reference resistance, determining a second lower threshold by subtracting the parallel deviation from the second reference resistance, and determining the second resistance zone based on the second upper threshold and the second lower threshold.

### Advantageous Effects

The present invention can determine a reference value for determining defects of battery banks, on the basis of a value corresponding to the number of battery cells connected in parallel, not on the basis of a fixed value, thereby diagnosing defects of battery banks including battery cells connected in parallel, with high accuracy.

The present invention can finally estimate defective battery banks through a first defect diagnosis method of diagnosing defects on the basis of the internal resistance of battery banks and a second defect diagnosis method of diagnosing defects on the basis of the states of charge (SOC) of battery banks, whereby the accuracy of diagnosis can improve.

The present invention can improve the accuracy of diagnosis and predict the battery replacement cycle with high accuracy, thereby saving the battery replacement cost.

### DESCRIPTION OF THE DRAWINGS

FIG. 1 is a drawing for explaining a battery system according to an exemplary embodiment.

FIG. 2 is a drawing illustrating an example for explaining a first resistance zone according to the exemplary embodiment.

FIG. 3 is a drawing illustrating an example for explaining a second resistance zone according to the exemplary embodiment.

FIG. 4 is a flow chart for explaining a battery diagnosis method according to an exemplary embodiment.

FIG. 5 is a flow chart for explaining the first defect diagnosis step S100 of FIG. 4 in detail.

FIG. 6 is a flow chart for explaining the second defect diagnosis step S200 of FIG. 4 in detail.

### MODE FOR INVENTION

Hereinafter, exemplary embodiments disclosed in this specification will be described in detail with reference to the accompanying drawings; however, the same or similar constituent components are denoted by the same or similar reference symbols, and a repeated description thereof will not be made. As used herein, the suffix ‘module’ and/or the suffix ‘unit’ for constituent elements are given and used interchangeably in consideration of only ease of preparing this specification, and the suffixes themselves do not have meanings or roles distinguishable from each other. Further, when describing exemplary embodiments disclosed in this specification, detailed descriptions of publicly known technologies will be omitted if it is determined that specific description thereof may obscure the gist of the exemplary embodiments disclosed in this specification. Furthermore, the accompanying drawings are provided for helping to easily understand exemplary embodiments disclosed in the present specification, and the technical spirit disclosed in the present specification is not limited by the accompanying drawings, and it will be appreciated that the present invention includes all of the modifications, equivalent matters, and substitutes included in the spirit and the technical scope of the present invention.

Terms including an ordinal number, such as first and second, are used for describing various constituent elements, but the constituent elements are not limited by the terms. The terms are used only to discriminate one constituent element from another constituent element.

When a constituent element is referred to as being “connected” or “coupled” to another constituent element, it will be appreciated that it may be directly connected or coupled to the other constituent element or intervening other constituent elements may be present. In contrast, when a constituent element is referred to as being “directly connected” or “directly coupled” to another constituent element, it will be appreciated that there are no intervening other constituent elements present.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

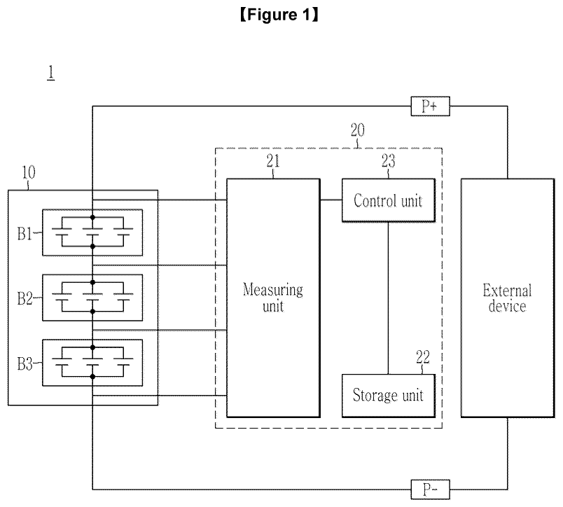

FIG. 1 is a drawing for explaining a battery system according to an exemplary embodiment.

Referring to FIG. 1, a battery system 1 includes a battery 10 and a BMS 20.

The battery 10 may include a plurality of battery banks connected in series and/or in parallel. Each battery bank may include a plurality of battery cells connected in parallel. Each battery cell refers to one independent cell which has a cathode terminal and an anode terminal and can be physically separated. For example, one pouch type lithium polymer cell may be regarded as a battery cell.

FIG. 1 shows that the battery 10 includes three battery banks B1, B2, and B3 connected in series and each of the three battery banks B1, B2, and B3 includes three battery cells connected in parallel. However, the present invention is not limited thereto, and the battery 10 may include a plurality of battery banks which is connected in parallel and each of which includes a plurality of battery cells. Hereinafter, each of the plurality of battery banks included in the battery 10 may include a plurality of battery cells having the same connection structure (series connections and parallel connections). In other words, parallel coefficients (μ) to be described may be the same.

The BMS 20 includes a measuring unit 21, a storage unit 22, and a control unit 23. FIG. 1 shows that the BMS 20 is included in the battery system 1; however, the present invention is not limited thereto, and the BMS may be mounted outside the battery system 1. Also, for example, the BMS 20 may be mounted in various systems requiring defect diagnosis on battery banks, and may function as a defect diagnosis device for the battery 10.

The measuring unit 21 may include a voltage sensor (not shown in the drawings) for measuring a bank voltage which is the voltage between both terminals of each of the plurality of battery banks, and a current sensor (not shown in the drawings) for measuring a bank current which is the current flowing through each of the plurality of battery banks. The measuring unit 21 may transmit the measurement results to the control unit 23.

With respect to each of the plurality of battery banks, the measuring unit 21 may measure a bank voltage V1 at a first time when charging of the battery 10 starts, and measure a bank voltage V2 at a second time that is a predetermined time later from the first time. The control unit 23 may calculate the voltage difference between the voltages of the battery bank measured at the first time and the second time, respectively (ΔV=|V1−V2|).

With respect to each of the plurality of battery banks, the measuring unit 21 may measure the bank voltage and the bank current in a charging mode or a discharging mode. In this case, the bank current may be a charging current or a discharging current. For example, in the charging mode, with respect to each of the plurality of battery banks, the control unit 23 may determine the internal resistance on the basis of the voltage difference (ΔV=|V2−V1|) and the charging current. Hereinafter, it is assumed that the battery banks is capable of charging and/or discharging at constant current.

With respect to each of the plurality of battery banks, the storage unit 22 may store an internal resistance value which the control unit 23 estimates on the basis of at least one of the bank voltage and the bank current. With respect to each of the plurality of battery banks, the storage unit may store the state of charge (SOC) which the control unit 23 estimates on the basis of at least one of the bank voltage and the bank current. By various known prior methods, the control unit 23 may estimate the internal resistance value and the state of charge (SOC) relative to each of the plurality of battery banks.

The control unit 23 may perform a first defect diagnosis of determining first diagnosis banks on the basis of the internal resistance values of the plurality of battery banks. The control unit 23 may perform a second defect diagnosis of determining second diagnosis banks on the basis of the states of charge (SOC) of the plurality of battery banks. In this case, the first diagnosis banks are battery banks determined as abnormal as the result of the first defect diagnosis. The second diagnosis banks are battery banks determined as abnormal as the result of the second defect diagnosis. According to the exemplary embodiment, a battery bank determined as normal during the first defect diagnosis may be used as a reference battery bank during the second defect diagnosis.

For example, the control unit 23 may perform the second defect diagnosis on all of the plurality of battery banks, regardless of the result of the first defect diagnosis. For another example, the control unit 23 may perform the second defect diagnosis on only battery banks determined as first diagnosis banks among the plurality of battery banks during the first defect diagnosis. In this case, the number of diagnosis objects of the second defect diagnosis decreases, so the diagnosis time can be saved.

According to the exemplary embodiment, the control unit 23 may diagnose, as defective battery banks, battery banks determined as first diagnosis banks and second diagnosis banks among plurality of battery banks. According to another exemplary embodiment, the control unit 23 may diagnose battery banks of the plurality of battery banks determined as second diagnosis banks, as defective battery banks.

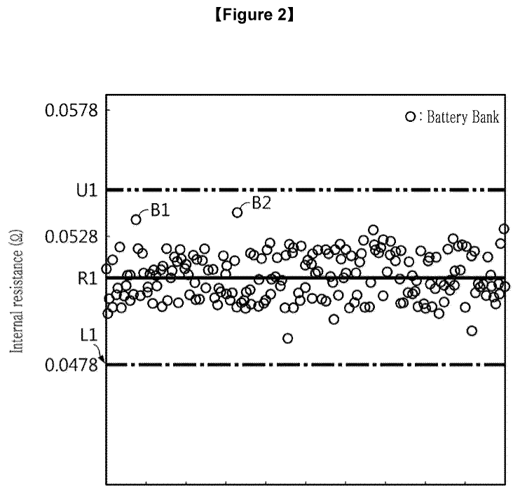

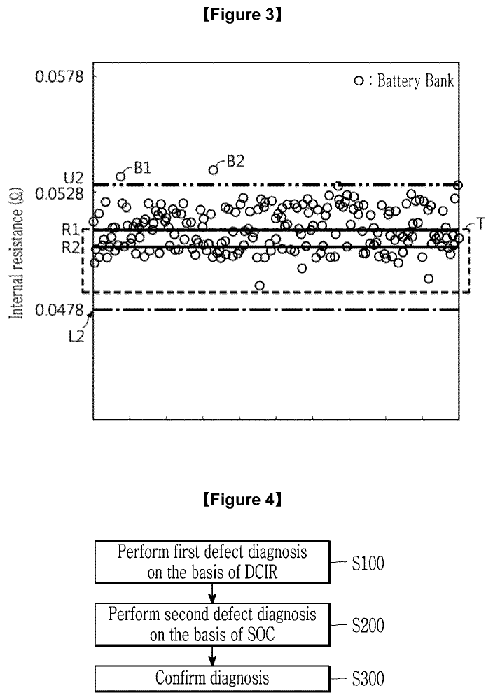

Hereinafter, a method of determining a first resistance zone and a second resistance zone for the first defect diagnosis will be described in detail with reference to FIG. 2 and FIG. 3.

FIG. 2 is a drawing illustrating an example for explaining a first resistance zone according to the exemplary embodiment.

Referring to FIG. 2, the control unit 23 may determine first reference resistance and a resistance deviation on the basis of a plurality of first internal resistance values related to the plurality of battery banks, and determine a first resistance zone on the basis of the first reference resistance and the resistance deviation.

First, the control unit 23 may calculate the internal resistance value of each of the plurality of battery banks on the basis of the following Equation 1.

$${DCIR}_{i} = \frac{Δ {V}_{i}}{I} \qquad Equation 1$$

Here, DCIR is the internal resistance (Ω) of a battery bank, and I is the bank current (mA). ΔV is a change in the voltage (mV) of the battery bank for a predetermined time. i is an index identifying each battery bank, and may be equal to or larger than 1 and equal to or smaller than n. n may be the total number of the plurality of battery banks to undergo state diagnosis by a battery diagnosis apparatus 100.

For example, the control unit 23 may calculate the difference between a first voltage V1 and a second voltage V2 of a battery bank, i.e., the voltage difference (ΔV=|V2−V1|). Since the magnitude of the charging current (I) for the battery bank is constant, the control unit 23 may calculate the internal resistance (DCIR) of the battery bank on the basis of the voltage difference (ΔV) and the bank current (I). In this case, the first voltage V1 may be the bank voltage measured at the first time when charging started, and the second voltage V2 may be bank voltage measured at the second time that was a predetermined time later from the first time.

Subsequently, the control unit 23 may set the median value or average of the plurality of internal resistance values of the plurality of battery banks, as a first reference resistance R1. It may be preferable that a first reference resistance R1 be the median value of the internal resistance values of a plurality of battery banks. Specifically, the control unit 23 may set an internal resistance value which is positioned at the center when the internal resistance values of the plurality of battery banks are arranged in the order of magnitude, as a first reference resistance R1.

Next, the control unit 23 may calculate the median absolute deviation (D) of the plurality of internal resistance values of the plurality of battery banks related to the first reference resistance R1, and convert the median absolute deviation (D) into a resistance deviation, using a predetermined scale constant.

For example, the control unit 23 may calculate the median absolute deviation (D) of the plurality of internal resistance values of the plurality of battery banks related to the first reference resistance R1, using the following Equation 2.

$$D = median ( \vert {DCIR}_{i} - R 1 \vert ) , ( 1 \leq i \leq n ) \qquad Equation 2$$

Here, i is an index indicating each battery bank, and may be equal to or larger than 1 and equal to or smaller than n. n may be the total number of the plurality of battery banks to be diagnosed. R1 is a first reference resistance, and DCIRᵢ is the internal resistance of the i-th battery bank. Median ( ) is a function that outputs the median value related to |DCIRᵢ−R1|, and D may be the median absolute deviation (hereinafter, referred to as the absolute deviation). In other words, D may be an absolute deviation between the first reference resistance R1 and the internal resistance (DCIRᵢ) values of the plurality of battery banks.

For example, the control unit 23 may calculate a scale constant, using the following Equation 3, and convert the absolute deviation into a resistance deviation, using the following Equation 4.

$$C = - \frac{1}{\sqrt{2} \times erfcinv ( a )} \qquad Equation 3$$

Here, C is a scale constant, and erfcinv(a) is an inverse complementary error function, and a is a constant. For example, when a is 3/2, erfcinv(3/2) may be the output value of the inverse complementary error function related to the input value 3/2.

$$S = D \times C \qquad Equation 4$$

Here, S is a resistance deviation that is obtained by conversion, and D is an absolute deviation according to Equation 2, and C is a scale constant according to Equation 3.

Next, the control unit 23 may determine a first resistance zone on the basis of the first reference resistance R1 and the resistance deviation S.

Specifically, referring to FIG. 2, the control unit 23 may calculate a first upper threshold U1 by adding the resistance deviation S to the first reference resistance R1. In other words, the control unit 23 may calculate the first upper threshold U1 by calculating “R1+S”. Also, the control unit 23 may calculate a first lower threshold L1 by subtracting the resistance deviation from the first reference resistance R1. In other words, the control unit 23 may calculate the first lower threshold L1 by calculating “R1−S”.

Referring to FIG. 2, the Y-axis represents internal resistance (Ω), and the X-axis may represent the serial numbers of battery banks. In other words, the values on the X-axis are values independent from internal resistance values, and any factor capable of identifying each of the plurality of battery banks may be applied without limitation.

For example, a first lower threshold L1 and a first upper threshold U1 may be set symmetrically relative to the first reference resistance R1. The resistance zone from the first lower threshold L1 to the first upper threshold U1 may be set as the first resistance zone. Further, in the exemplary embodiment of FIG. 2, all of the internal resistance values of the plurality of battery banks may be included in the first resistance zone.

FIG. 3 is a drawing illustrating an example for explaining a second resistance zone according to the exemplary embodiment.

Referring to FIG. 3, the control unit 23 may determine, as target banks, a plurality of battery banks having internal resistance values smaller than the first reference resistance R1 among the plurality of battery banks. The control unit 23 may determine a second reference resistance R2 on the basis of a plurality of second internal resistance values related to the plurality of target banks. The control unit 23 may determine a second resistance zone on the basis of the second reference resistance R2 and a parallel deviation. In this case, a parallel deviation P may be a value corresponding to the connection structure of a plurality of battery cells included in a target bank.

First, the control unit 23 may determine, as target banks, a plurality of battery banks having internal resistance values smaller than the first reference resistance R1 among the plurality of battery banks.

As the first reference resistance R1, the median value or average of the plurality of battery banks may be applied. In the case where the first reference resistance R1 is the average of the internal resistance values of the plurality of battery banks, battery banks having internal resistance values equal to or smaller than the average may be selected as target banks. On the contrary, in the case where the first reference resistance R1 is the median value of the internal resistance values of the plurality of battery banks, battery banks having internal resistance values included in the bottom 50% may be selected as target banks.

Subsequently, the control unit 23 may determine a second reference resistance R2 on the basis of a plurality of second internal resistance values related to the plurality of target banks.

The second reference resistance R2 is a value representing the internal resistance values of the plurality of target banks, and may be the median value, the average, or the like. It may be preferable that the second reference resistance R2 be the average of the plurality of internal resistance values of the plurality of target banks.

Next, the control unit 23 may calculate a parallel coefficient μ from the number of parallel connections, and calculate a parallel deviation P by multiplying the parallel coefficient μ and the second reference resistance R2 together.

For example, the control unit 23 may calculate a parallel coefficient using the following Equation 5. Here, u is a parallel coefficient, and m is the number of parallel connections. b is a constant, and may be, for example, 0 or 1. In other words, the parallel coefficient μ may be related to the reciprocal of the number of parallel connections (m).

$$μ = \frac{1}{m - b} \qquad Equation 5$$

For example, the control unit 23 may calculate a parallel deviation P using the following Equation 6. Here, P is a parallel deviation, and R2 is a second reference resistance, and μ is a parallel coefficient according to Equation 5.

$$P = R 2 \times μ \qquad Equation 6$$

Next, the control unit 23 may determine a second resistance zone on the basis of the second reference resistance R2 and the parallel deviation P.

Specifically, the control unit 23 may calculate a second upper threshold U2 by adding the parallel deviation P to the second reference resistance R2. In other words, the control unit 23 may calculate a second upper threshold U2 by calculating “R2+P”. The control unit 23 may calculate a second lower threshold L2 by subtracting the parallel deviation P from the second reference resistance R2. In other words, the control unit 23 may calculate a second lower threshold L2 by calculating “R2−P”.

Referring to FIG. 3, the Y-axis represents internal resistance (Ω), and the X-axis may represent the serial numbers of battery banks. In other words, the values on the X-axis are values independent from internal resistance, and any factor capable of identifying each of the plurality of battery banks may be applied without limitation. Specifically, in the exemplary embodiments of FIG. 2 and FIG. 3, the plurality of battery banks may be identical.

For example, a second lower threshold L2 and a second upper threshold U2 may be set symmetrically relative to the second reference resistance R2. The resistance zone from the second lower threshold L2 to the second upper threshold U2 may be set as a second resistance zone.

The control unit 23 may determine first diagnosis banks in the light of both of the first resistance zone and the second resistance zone, not in the light of only one of the first resistance zone and the second resistance zone.

Preferably, the control unit 23 may determine that battery banks having internal resistance values belonging to both of the first resistance zone and the second resistance zone among the plurality of battery banks are normal. The control unit 23 may determine that battery banks having internal resistance which is out of the first resistance zone or the second resistance zone among the plurality of battery banks are abnormal, and determine them as first diagnosis banks. According to an exemplary embodiment, the battery banks determined as normal during the first defect diagnosis may be used as reference battery banks for the second defect diagnosis.

For example, referring to FIG. 2, the internal resistance values of a first battery bank B1 and a second battery bank B2 of the plurality of battery banks may be included in the first resistance zone. However, referring to FIG. 3, the internal resistance values of the first battery bank B1 and the second battery bank B2 may not be included in the second resistance zone. In this case, the control unit 23 may determine the first battery bank B1 and the second battery bank B2 as first diagnosis banks, and then further diagnose whether there is any defect, on the basis of the state of charge (SOC).

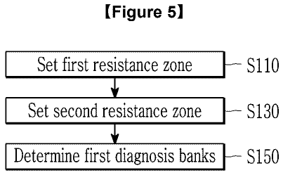

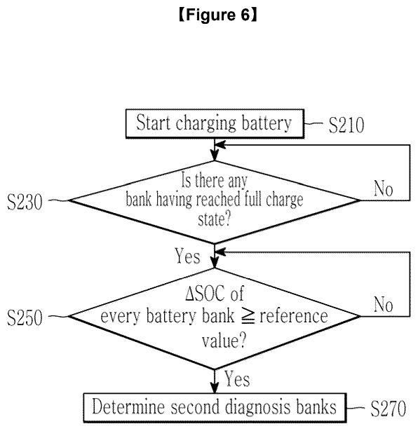

FIG. 4 is a flow chart for explaining a battery diagnosis method according to an exemplary embodiment, and FIG. 5 is a flow chart for explaining the first defect diagnosis step S100 of FIG. 4 in detail, and FIG. 6 is a flow chart for explaining the second defect diagnosis step S200 of FIG. 4 in detail.

Hereinafter, on the basis of FIG. 1 to FIG. 6, a method of diagnosing defects of a plurality of battery banks and a battery system for providing the method will be described.

Referring to FIG. 4, first, the control unit 23 performs a first defect diagnosis on the plurality of battery banks on the basis of the internal resistance (DCIR) (S100).

In step S100, referring to FIG. 5, the control unit 23 determines a first reference resistance and a resistance deviation on the basis of a plurality of first internal resistance values related to the plurality of battery banks, and determines a first resistance zone on the basis of the first reference resistance and the resistance deviation (S110).

For example, the control unit 23 may set the median value of the plurality of internal resistance values of the plurality of battery banks, as a first reference resistance R1. The control unit 23 may calculate the median absolute deviation (D) between the first reference resistance R1 and the internal resistance values of the plurality of battery banks, using the above Equation 2. The control unit 23 may determine a scale constant using the above Equation 3, and convert the median absolute deviation (D) into a resistance deviation S using the above Equation 4.

The control unit 23 may calculate a first upper threshold U1 by adding the resistance deviation S to the first reference resistance R1. The control unit 23 may calculate a first lower threshold L1 by subtracting the resistance deviation S from the first reference resistance R1. Referring to FIG. 2, the control unit 23 may determine the resistance zone from the first lower threshold L1 to the first upper threshold U1, as a first resistance zone.

In step S100, the control unit 23 determines, as target banks, a plurality of battery banks having internal resistance values smaller than the first reference resistance R1 among the plurality of battery banks, and determines a second reference resistance R2 on the basis of a plurality of second internal resistance values related to the plurality of target banks, and determines a second resistance zone on the basis of the second reference resistance R2 and a parallel deviation (S130).

For example, in the case where the first reference resistance R1 is the median value of the internal resistance values of the plurality of battery banks, the control unit 23 may select, as target banks, battery banks having internal resistance values included in the bottom 50%.

The control unit 23 may determine the average of the internal resistance values of the plurality of target banks, as a second reference resistance R2. Also, the control unit 23 may calculate a parallel coefficient μ from the number of parallel connections (m), and calculate a parallel deviation P by multiplying the parallel coefficient μ and the second reference resistance R2 together. For example, the control unit 23 may calculate a parallel coefficient μ using the above Equation 5, and calculate a parallel deviation P using the above Equation 6. In this case, the parallel deviation P may be a value corresponding to the connection structure of a plurality of battery cells included in a target bank.

The control unit 23 may calculate a second upper threshold U2 by adding the parallel deviation P to the second reference resistance R2. The control unit 23 may calculate a second lower threshold L2 by subtracting the parallel deviation P from the second reference resistance R2. Referring to FIG. 3, the control unit 23 may determine the resistance zone from the second lower threshold L2 to the second upper threshold U2, as a second resistance zone.

In step S100, the control unit 23 determines, as first diagnosis banks, battery banks having internal resistance values which are out of the first resistance zone or the second resistance zone among the plurality of battery banks (S150).

For example, referring to FIG. 2, the internal resistance values of a first battery bank B1 and a second battery bank B2 of the plurality of battery banks may be included in the first resistance zone. However, referring to FIG. 3, the internal resistance of the first battery bank B1 and the second battery bank B2 may not be included in the second resistance zone. In this case, the control unit 23 may determine the first battery bank B1 and the second battery bank B2 as first diagnosis banks.

Subsequently, the control unit 23 performs a second defect diagnosis on the battery banks on the basis of the states of charge (SOC) of the plurality of battery banks (S200).

According to an exemplary embodiment, the control unit 23 may perform a second defect diagnosis on the first diagnosis banks. According to another exemplary embodiment, the control unit 23 may perform a second defect diagnosis on the plurality of battery banks.

Referring to FIG. 6, in step S200, when a predetermined condition is satisfied, the control unit 23 proceeds to a charging mode of charging the battery 10 with the electricity of an external device (S210).

For example, in the case where a state-of-charge (SOC) range equal to or larger than 20% and smaller than 80% is set as a battery use range, when the state of charge (SOC) of the battery 10 reaches 20%, the control unit 23 may perform the charging mode.

In step S200, the control unit 23 determines whether a first diagnosis condition that there should be at least one battery bank having reached a state of charge (SOC) indicating a full charge state among the plurality of battery banks included in the battery 10 is satisfied (S230).

When a predetermined diagnosis condition is satisfied in the charging mode of charging the battery with the electricity of the external device, the control unit 23 may perform a second defect diagnosis in which it determines the ratios of second state-of-charge change amounts (ΔSOC2) of battery banks to a first state-of-charge change amount (ΔSOC1) of a reference battery bank (ΔSOC2/ΔSOC1), and determines second diagnosis banks by comparing the determined ratios with a diagnosis reference value.

For example, in the case where a state-of-charge (SOC) range equal to or larger than 20% and smaller than 80% is set as a battery use range, when the plurality of battery banks included in the battery 10 includes at least one battery bank in which the state of charge (SOC) has reached 80%, the control unit 23 may determine that some battery banks having reached a full charge state exist. In other words, the full charge state may be determined by the predetermined battery use range.

In step S200, when it is determined that the first diagnosis condition is satisfied (Yes in step S230), the control unit 23 determines whether a second diagnosis condition that the state-of-charge change amounts of the plurality of battery banks should be equal to or larger than a condition reference value is satisfied (S250).

For example, it is assumed that the condition reference value is 45%. In the case where the state-of-charge change amounts of the plurality of battery banks from the charging start time, i.e., their state-of-charge increases are equal to or larger than 45%, the control unit 23 may determine that the second diagnosis condition is satisfied.

For another example, it is assumed that in the middle of the charging mode, at a point of time, a first battery bank B1 has been fully charged from the state of charge of 20% to 80% (ΔSOC₁=60%), and a second battery bank B2 has been charged from the state of charge of 25% to 70% (ΔSOC₂=45%), and a third battery bank B3 has been charged from the state of charge of 25% to 72% (ΔSOC₃=47%), and a fourth battery bank B4 has been charged from the state of charge of 25% to 70% (ΔSOC₄=45%), and a fifth battery bank B5 has been charged from the state of charge of 20% to 70% (ΔSOC₅=50%). The control unit 23 may determine that the first diagnosis condition is satisfied, because the first battery bank B1 has reached the full charge state (SOC=80%), and determine that the second diagnosis condition is satisfied, because the state-of-charge change amounts of the first to fifth battery banks B1, B2, B3, B4, and B5 (ΔSOC₁₋₅=60%, 45%, 47%, 45%, 50%) are equal to or larger than the condition reference value (45%). In other words, the control unit 23 may determine that the first diagnosis condition and the second diagnosis condition are satisfied.

In step S200, when it is determined that the second diagnosis condition is satisfied (Yes in S250), the control unit 23 determines the ratios of the second state-of-charge change amounts of battery banks to the first state-of-charge change amount of the reference battery bank, and determines second diagnosis banks by comparing the ratios with the diagnosis reference value (S270).

As the reference battery bank, a battery bank diagnosed as normal or a new battery bank which has never been used may be determined. According to an exemplary embodiment, the reference battery bank may be a battery bank determined as normal in the first defect diagnosis step. For example, in the case where a plurality of battery banks has been determined as normal in the first defect diagnosis step, the control unit 23 may determine, as a reference battery bank, a battery bank having the smallest state-of-charge change amount (ΔSOC) calculated in the second defect diagnosis step. However, the present invention is not limited thereto, and the control unit 23 may determine, as a reference battery bank, one of the plurality of battery banks determined as being normal during the first defect diagnosis.

For example, it is assumed that the battery 10 includes first to fifth battery banks B1 to B5, and in the first defect diagnosis step, the first and second battery banks B1 and B2 are diagnosed as first diagnosis banks corresponding to the abnormal state, and the third to fifth battery banks B3, B4, and B5 are diagnosed as normal. In the second defect diagnosis step, when it is assumed that the state-of-charge change amounts (ΔSOC₁₋₃) of the third to fifth battery banks B3, B4, and B5 are 47%, 45%, and 50%, respectively, the control unit 23 may determine the fourth battery bank B4 having the smallest state-of-charge change amount, as a reference battery bank.

The diagnosis reference value may be determined on the basis of the number of battery cells connected in parallel in a battery bank. For example, the diagnosis reference value may be determined by the following Equation 7.

$${Th}_{1} = \frac{m}{m - n} \qquad Equation 7$$

Here, Th1 is a diagnosis reference value, and m is the number of battery cells connected in parallel in a battery bank, and n is a natural number smaller than m.

For example, when it is desired to diagnose a case where at least one battery cell is defective, n may be set to 1. For another example, when it is desired to diagnose a case where two or more battery cells are defective as a case where there are some defective battery cells, n may be set to 2. In other words, when it is desired to detect battery banks each of which includes at least one defect battery cell, n in the above Equation 7 may be set to 1. Hereinafter, it is assumed that m is 5 and n is 1. In this case, the diagnosis reference value Th1 may be set to 1.25.

For example, it is assumed that the state of charge of a reference battery bank has changed from 25% to 70%, and the state of charge of a first battery bank B1 has changed from 20% to 80%. Since the ratio of a second state-of-charge change amount which is the state-of-charge change amount of the first battery bank (60%=80%-20%) to a first state-of-charge change amount which is the state-of-charge change amount of the reference battery bank (45%=70%-25%) (1.33=60%/45%) is equal to or larger than the diagnosis reference value (Th1=1.25), the control unit 23 may determine the first battery bank B1 as a second diagnosis bank.

Subsequently, the control unit 23 diagnoses, as defective battery banks, battery banks determined as first diagnosis banks and second diagnosis banks among the plurality of battery banks (S300).

According to an exemplary embodiment, the accuracy of diagnosis can be improved by finally diagnosing defective battery banks by a first defect diagnosis method of diagnosing defects on the basis of the internal resistance of battery banks and a second defect diagnosis method of diagnosing defects on the basis of the states of charge (SOC) of battery banks.

According to another exemplary embodiment, the control unit 23 may diagnose defective battery banks by only the second defect diagnosis method of diagnosing defects on the basis of the states of charge (SOC) of battery banks. In this case, the control unit 23 may determine a reference battery bank by the first defect diagnosis method described above, and determine second diagnosis banks on the basis of the state-of-charge change amount ratios between the reference battery bank and battery banks. The second diagnosis banks may be defective battery banks.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

1. A battery system comprising:
a battery that includes a plurality of battery banks, each of which includes a plurality of battery cells; and
a control unit configured to determine a ratio of second state-of-charge change amounts of each battery bank to a first state-of-charge change amount of a reference battery bank, and diagnose defects of each battery bank by comparing the ratio with a diagnosis reference value, when a predetermined diagnosis condition is satisfied in a charging mode of charging the battery with electricity of an external device,
wherein the diagnosis reference value is determined based on a number of battery cells connected in parallel in a respective battery bank.

2. The battery system of claim 1, wherein
the diagnosis reference value is determined by a following equation:
$${Th}_{1} = \frac{m}{m - n} \qquad Equation$$
wherein Th₁ is the diagnosis reference value, m is the number of battery cells connected in parallel in the battery bank, and n is a natural number smaller than m.

3. The battery system of claim 1, wherein in the charging mode, when a first diagnosis condition that at least one battery bank reaches a full charge state and a second diagnosis condition that the second state-of-charge change amount of each of the plurality of battery banks is equal to or larger than a condition reference value including the first state-of-charge change amount of the reference battery bank, are satisfied, the control unit diagnoses a defect of the plurality of battery banks.

4. The battery system of claim 1, wherein the control unit is further configured to:
determine a first reference resistance and a resistance deviation on the basis of a plurality of first internal resistance values related to the plurality of battery banks, and determining a first resistance zone based on the first reference resistance and the resistance deviation;
determine, as target banks, a plurality of battery banks having internal resistance values smaller than the first reference resistance among the plurality of battery banks, determine a second reference resistance on the basis of a plurality of second internal resistance values related to a plurality of target banks, and determine a second resistance zone based on the second reference resistance and a parallel deviation corresponding to a connection structure of the plurality of battery cells included in each target bank; and
determine, as the reference battery bank, a battery bank having an internal resistance value belonging to the first resistance zone and the second resistance zone among the plurality of battery banks.

5. A battery system comprising:
a battery that includes a plurality of battery banks, each of which includes a plurality of battery cells; and
a control unit configured to determine first diagnosis banks based on an internal resistance of the plurality of battery banks, determine second diagnosis banks by comparing a ratio of a second state-of-charge change amounts of battery banks to a first state-of-charge change amount of a reference battery bank with a diagnosis reference value, when a predetermined diagnosis condition is satisfied in a charging mode of charging the battery with electricity of an external device, and diagnose, as defective battery banks, battery banks determined as the first diagnosis banks and the second diagnosis banks among the plurality of battery banks,
wherein the diagnosis reference value is determined based on a number of battery cells connected in parallel in a respective battery bank.

6. The battery system of claim 5, wherein the diagnosis reference value is determined by a following equation:
$${Th}_{1} = \frac{m}{m - n} \qquad Equation$$
wherein Th₁ is the diagnosis reference value, m is the number of battery cells connected in parallel in a battery bank, and n is a natural number smaller than m.

7. The battery system of claim 5, wherein in the charging mode, when a first diagnosis condition that at least one battery bank reaches a full charge state and a second diagnosis condition that the second state-of-charge change amount of each of the plurality of battery banks is equal to or larger than a condition reference value including the first state-of-charge change amount of the reference battery bank, are satisfied, the control unit determines the second diagnosis banks.

8. The battery system of claim 5, wherein the control unit is further configured to:
determine a first reference resistance and a resistance deviation on the basis of a plurality of first internal resistance values related to the plurality of battery banks, and determining a first resistance zone based on the first reference resistance and the resistance deviation;
determine, as target banks, a plurality of battery banks having internal resistance values smaller than the first reference resistance among the plurality of battery banks, determine a second reference resistance on the basis of a plurality of second internal resistance values related to a plurality of target banks, and determine a second resistance zone based on the second reference resistance and a parallel deviation corresponding to a connection structure of the plurality of battery cells included in each target bank; and
determine, as the first diagnosis bank, a battery bank having an internal resistance value which is out of the first resistance zone or the second resistance zone among the plurality of battery banks.

9. The battery system of claim 7, wherein the control unit is further configured to determine, as the reference battery bank, a battery bank having an internal resistance value belonging to the first resistance zone and the second resistance zone among the plurality of battery banks.

10. The battery system of claim 8, wherein the control unit is further configured to:
determine a median value of the plurality of first internal resistance values as the first reference resistance; and
determine an absolute deviation between the first reference resistance and the internal resistance of the plurality of battery banks, and convert the absolute deviation into the resistance deviation, using a predetermined scale constant.

11. The battery system of claim 10, wherein the control unit is further configured to determine a first upper threshold by adding the resistance deviation to the first reference resistance, and determine a first lower threshold by subtracting the resistance deviation from the first reference resistance, and determine the first resistance zone based on the first upper threshold and the first lower threshold.

12. The battery system of claim 8, wherein the control unit is further configured to:
determine an average of the plurality of second internal resistance values as the second reference resistance; and
determine a parallel coefficient based on the number of battery cells connected in parallel included in each target bank, and determine the parallel deviation by multiplying the parallel coefficient and the second reference resistance together.

13. The battery system of claim 12, wherein the control is further configured to:
determine a second upper threshold by adding the parallel deviation to the second reference resistance;
determine a second lower threshold by subtracting the parallel deviation from the second reference resistance; and
determine the second resistance zone based on the second upper threshold and the second lower threshold.

14. The battery system of claim 5, further comprising:
a measuring unit that is configured to measure a bank voltage, which is a voltage between both terminals of each of the plurality of battery banks, and a bank current which is a current flowing through each of the plurality of battery banks; and
a storage unit that is configured to store an internal resistance value and a state of charge (SOC) which is estimated based on at least one of the bank voltage and the bank current.

15. A method of diagnosing defects of a battery including a plurality of battery banks, each of which includes a plurality of battery cells, comprising:
a first defect diagnosis step of determining first diagnosis banks based on an internal resistance of the plurality of battery banks;
a second defect diagnosis step of determining second diagnosis banks by comparing a ratio of second state-of-charge change amounts of battery banks to a first state-of-charge change amount of a reference battery bank with a diagnosis reference value, when a predetermined diagnosis condition is satisfied in a charging mode of charging the battery with electricity of an external device; and
a diagnosis confirming step of diagnosing, as defective battery banks, battery banks determined as the first diagnosis banks and the second diagnosis banks among the plurality of battery banks,
wherein the diagnosis reference value is determined based on a number of battery cells connected in parallel in a respective battery bank.

16. The battery diagnosis method of claim 15, wherein the diagnosis reference value is determined by a following equation:
$${Th}_{1} = \frac{m}{m - n} \qquad Equation$$
wherein Th₁ is the diagnosis reference value, m is the number of battery cells connected in parallel in a battery bank, and n is a natural number smaller than m.

17. The battery diagnosis method of claim 15, wherein in the charging mode, when a first diagnosis condition that at least one battery bank should reach a full charge state and a second diagnosis condition that the second state-of-charge change amount of each of the plurality of battery banks should be equal to or larger than a condition reference value including the first state-of-charge change amount of the reference battery bank, are satisfied, the second defect diagnosis step determines the second diagnosis banks.

18. The battery diagnosis method of claim 15, wherein the first defect diagnosis step further includes:
a step of determining a first reference resistance and a resistance deviation on the basis of a plurality of first internal resistance values related to the plurality of battery banks, and determining a first resistance zone based on the first reference resistance and the resistance deviation;
a step of determining, as target banks, a plurality of battery banks having internal resistance values smaller than the first reference resistance among the plurality of battery banks, and determining a second reference resistance on the basis of a plurality of second internal resistance values related to a plurality of target banks, and determining a second resistance zone on the basis of the second reference resistance and a parallel deviation corresponding to a connection structure of the plurality of battery cells included in each target bank; and
a step of determining the first diagnosis banks and the reference battery bank by comparing the internal resistance value of each of the plurality of battery banks with the first resistance zone and the second resistance zone.

19. The battery diagnosis method of claim 18, wherein the step of determining the first resistance zone includes:
determining a median value of the plurality of first internal resistance values as the first reference resistance; and
determining an absolute deviation between the first reference resistance and the internal resistance of the plurality of battery banks, and converting the absolute deviation into the resistance deviation, using a predetermined scale constant.

20. The battery diagnosis method of claim 19, wherein the step of determining the first resistance zone further includes determining a first upper threshold by adding the resistance deviation to the first reference resistance, determining a first lower threshold by subtracting the resistance deviation from the first reference resistance, and determining the first resistance zone based on the first upper threshold and the first lower threshold.

21. The battery diagnosis method of claim 18, wherein the step of determining the second resistance zone includes:
determining an average of the plurality of second internal resistance values as the second reference resistance; and
determining a parallel coefficient based on the number of battery cells connected in parallel included in each target bank, and determining the parallel deviation by multiplying the parallel coefficient and the second reference resistance together.

22. The battery diagnosis method of claim 21, wherein the step of determining the second resistance zone further includes:
determining a second upper threshold by adding the parallel deviation to the second reference resistance;
determining a second lower threshold by subtracting the parallel deviation from the second reference resistance; and
determining the second resistance zone based on the second upper threshold and the second lower threshold.
